(19) United States
(12) Patent Application Publication
(10) Pub. No.: US 2025/0324841 A1
(43) Pub. Date: Oct. 16, 2025

(54) ELECTRONIC DEVICE

(71) Applicants: InnoLux Corporation, Miao-Li County (TW); CARUX TECHNOLOGY PTE. LTD., APERIA (SG)

(72) Inventors: Yi-Wen YEN, Tainan (Tainan Science Park) (TW); Yu-Ting CHEN, Tainan (Tainan Science Park) (TW); Li-Wei SUNG, Tainan (Tainan Science Park) (TW); Xin ZHAO, Miao-Li County (TW); Cheng-Chun ZHOU, Miao-Li County (TW)

(21) Appl. No.: 19/079,684

(22) Filed: Mar. 14, 2025

(30) Foreign Application Priority Data
Apr. 15, 2024 (CN) 202410451437.0

(51) Int. Cl. H10H 29/855; H10K 59/80; H10K 59/88

(52) U.S. Cl. CPC H10H 29/8552; H10K 59/879; H10K 59/8792; H10K 59/88

(57) ABSTRACT

An electronic device is provided. The electronic device includes a display panel and a cover lens. The display panel has an active area. The cover lens is disposed corresponding to the display panel. The cover lens includes a substrate, a first alignment mark, and a second alignment mark. The first alignment mark is disposed on a surface of the substrate and corresponds to a first position in the active area. The second alignment mark is disposed on the surface of the substrate and corresponds to a second position in the active area. The second position differs from the first position. Wherein, a transmittance of the first alignment mark in a first alignment region is 20% to 99%.

### CROSS REFERENCE TO RELATED APPLICATIONS

This Application claims priority of China Patent Application No. 202410451437.0, filed on Apr. 15, 2024, the entirety of which is incorporated by reference herein.

### BACKGROUND

### Technical Field

The present disclosure relates to electronic device, and, in particular, to electronic device including alignment marks.

### Description of the Related Art

Electronic devices that include display panel, such as displays, smartphones, tablets, notebook computers, and televisions, have become indispensable necessities in modern society. With the booming development of this type of electronic device, consumers have high expectations for the quality, functionality, or price of these electronic devices.

In general, during the process of manufacturing electronic devices, it is often necessary to perform multiple bonding processes, so that different elements, films, and layers are bonded to each other to obtain the electronic devices. Since tolerances occur in the bonding process, the accuracy and/or process margin of the bonding process may be reduced, and the visual effects and/or reliability of the electronic device may be reduced. In addition, it may also result in the limitation that the electronic device cannot be easily applied to a device with a narrow frame or a device with a curved edge.

Therefore, these electronic devices do not meet consumer expectations in all respects, and there are still some problems in the electronic devices. The development of improved electronic devices is still one of the current goals.

### BRIEF SUMMARY

An embodiment of the present disclosure provides an electronic device. The electronic device includes a display panel and a cover lens. The display panel has an active area. The cover lens is disposed corresponding to the display panel. The cover lens includes a substrate, a first alignment mark, and a second alignment mark. The first alignment mark is disposed on a surface of the substrate and corresponds to a first position in the active area. The second alignment mark is disposed on the surface of the substrate and corresponds to a second position in the active area. The second position differs from the first position. Wherein, a transmittance of the first alignment mark in a first alignment region is 20% to 99%.

The electronic devices of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 is a schematic cross-sectional view of an electronic device according to some embodiments of the present disclosure.

FIGS. 2 to 6 are schematic bottom views of a cover lens of an electronic device according to some embodiments of the present disclosure, respectively.

FIG. 7 is a schematic cross-sectional view of an electronic device according to some embodiments of the present disclosure.

FIGS. 8 to 17 are schematic bottom views of a cover lens of an electronic device according to some embodiments of the present disclosure, respectively.

### DETAILED DESCRIPTION

Electronic devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar and/or corresponding reference numerals may be used in different embodiments to designate similar and/or corresponding elements in order to clearly describe the present disclosure. However, the use of these similar and/or corresponding reference numerals is only for the purpose of simply and clearly description of some embodiments of the present disclosure, and does not imply any correlation between the different embodiments and/or structures discussed.

It should be understood that relative terms, such as “lower”, “bottom”, “higher” or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second” and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to connection and bonding can also include embodiments in which both structures are movable, or in which both structures are fixed. Furthermore, the terms “electrically connected” or “electrically coupled” include any direct and indirect means of electrical connection.

Herein, the terms “about”, “approximately”, and “substantially” generally mean within 10%, within 5%, within 3%, within 2%, within 1%, or within 0.5% of a given value or range. The given value is an approximate value, that is, “about”, “approximately”, and “substantially” can still be implied without the specific description of “about”, “approximately”, and “substantially”. The phrase “a range between a first value and a second value”, “between a first value and a second value”, or “a first value to a second value (a first value-a second value)” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 1% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in this disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “comprising”, “including”, and “having” are open-ended words, so they should be interpreted as meaning “including but not limited to . . . ”. Therefore, when the terms “comprising”, “including”, and/or “having” is used in the description of the present disclosure, it designates the presence of corresponding features, regions, steps, operations, and/or elements, but does not exclude the presence of one or more corresponding features, regions, steps, operations, and/or elements.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (height/thickness direction). In some embodiments, the schematic bottom views described herein are schematic views observing the XY plane, the schematic cross-sectional views described herein are schematic views observing the XZ plane. In some embodiments, a normal direction of the display panel, the cover lens, and/or the substrate is the third direction.

In some embodiments of the present disclosure, the relative setting relationship, the depth, the thickness, the width, or the height of each element, as well as the pitch or distance between elements, may be measured using an optical microscope (OM), a scanning electron microscope (SEM), a film thickness profiler (α-step), an ellipsometer, or another suitable method. According to some embodiments, a cross-sectional structure image including an element to be measured may be obtained by using the scanning electron microscope, and then the depth, the thickness, the width, or the height of each element, and the pitch or the distance between elements, may be measured.

In some embodiments, when there is a “pitch” between two elements, the “pitch” represents the distance between the edge of one element and the edge of the other one element. In some embodiments, when an element has a “center”, the “center” represents the geometric center of the element, the center of a circle, the intersection of the diagonals of the smallest rectangle covering the element, or center otherwise defined.

In some embodiments, ultraviolet-visible spectrometers or other suitable methods may be used to measure the transmittance (unit: %) of the element. For example, an ultraviolet-visible (UV-visible) spectrometer of the brand: Jasco, model: V7100 can be used for measurement, but the present disclosure is not limited thereto. In some embodiments, an inkjet printer may be used to form the alignment marks. For example, an inkjet printer of the brand: NAKAN, model: NTJ-IP40160HM Robot Type can be used for measurement, but the present disclosure is not limited thereto.

In the present disclosure, the electronic device may include a display device, an antenna device, a packing device, a sensing device, or a titling device, but the present disclosure is not limited thereto. The electronic device may be a foldable or flexible electronic device. The display device may be a non-self-luminous display module or a self-luminous display module. The antenna device may be a liquid crystal antenna device or a varactor diodes antenna device, but the present disclosure is not limited thereto. The sensing device may be a sensing device for sensing capacitance, light, heat, or ultrasonic waves, but the present disclosure is not limited thereto. The electronic unit may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The packing device may be formed by Wafer Level Packaging (WLP) technology or Wafer Level Packaging (PLP) technology, such as chip-first process or redistribution layer-first (RDL-first) process. The titling device may be, for example, a display titling device or an antenna titling device, but the present disclosure is not limited thereto.

In addition, the shape of the electronic device may be rectangular, circular, polygonal, a shape with curved edges, or another suitable shape. The electronic device may have a peripheral system, such as a processing system, a driving system, a control system, a light source system, a shelf system, or the like to support the display module or titling module.

It should be understood that, for clarity of explanation, some elements of the electronic device may be omitted in the drawings, and only some elements are schematically illustrated. In some embodiments, additional elements may be added to the electronic device described below. In other embodiments, some elements of the electronic device described below may be replaced or omitted.

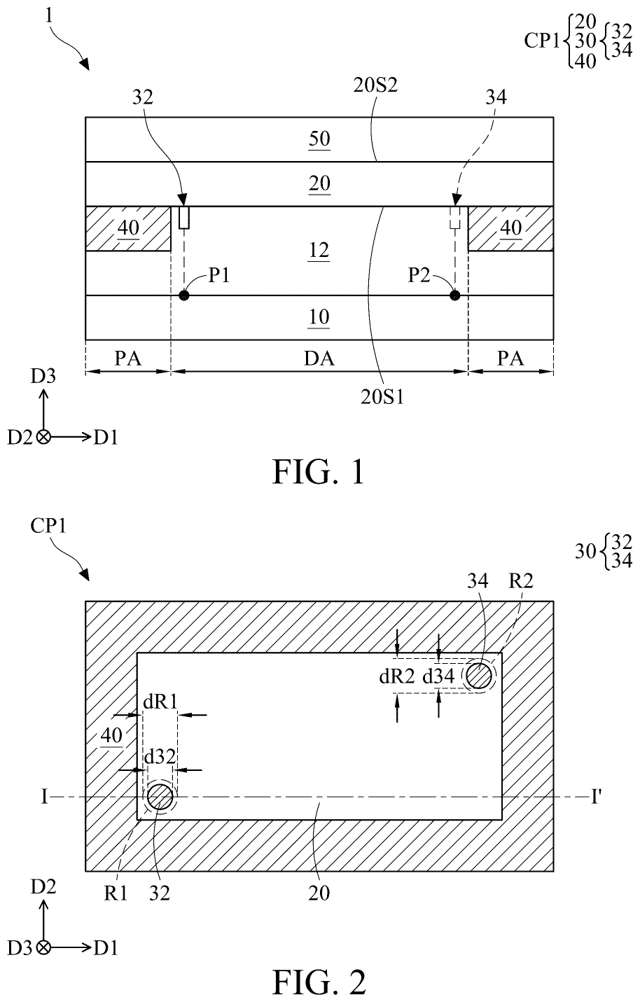

Referring to FIG. 1, which is a schematic cross-sectional view of the electronic device 1 according to some embodiments of the present disclosure. In some embodiments, the electronic device 1 may include a display panel 10 and a cover lens (also referred as a cover plate) CP1. In some embodiments, the display panel 10 may include a liquid crystal display panel, a light-emitting diode display panel, the like, or a combination thereof, but the present disclosure is not limited thereto. For example, the light-emitting diode display panel may include inorganic light-emitting diode display panel, organic light-emitting diode display panel, mini light-emitting diode display panel, micro light-emitting diode display panel, and quantum dot light-emitting diode display panel, the like, or a combination thereof, but the present disclosure is not limited thereto. In some embodiments, the display panel 10 may have an active area (also referred as a display area) DA and a peripheral area PA, and the peripheral area PA may surround the active area DA.

In some embodiments, the cover lens CP1 may be disposed corresponding to the display panel 10. In some embodiments, in a normal direction of the display panel 10 (that is, the third direction D3), the cover lens CP1 may be disposed on the display panel 10. In some embodiments, the cover lens CP1 may include a substrate 20, an alignment mark 30, and a light-shielding layer 40.

In some embodiments, the substrate 20 may include glass, quartz, sapphire, polyimide (PI), polydimethylsiloxane (PDMS), polycarbonate (PC), polyethylene terephthalate (PET), the like, or a combination thereof, but the present disclosure is not limited thereto. For example, the substrate 20 may include glass. In some embodiments, in the normal direction of the substrate 20 (that is, the third direction D3), the substrate 20 may have a bottom surface 20S1 and a top surface 20S2 opposite to each other.

In some embodiments, the alignment mark 30 may be disposed on the bottom surface 20S1 of the substrate 20. In some embodiments, the alignment mark 30 may correspond to the active area DA of the display panel 10. In some embodiments, the projection position of the alignment mark 30 on the display panel 10 may be located in the active area DA of the display panel 10.

In some embodiments, the light-shielding layer 40 may be disposed on the bottom surface 20S1 of the substrate 20. In some embodiments, the light-shielding layer 40 may correspond to the peripheral area PA of the display panel 10. In some embodiments, the projection position of the light-shielding layer 40 on the display panel 10 may be located in the peripheral area PA of the display panel 10. In some embodiments, the light-shielding layer 40 may surround the alignment mark 30.

As shown in FIG. 1, in some embodiments, the electronic device 1 may further include an adhesive layer 12. In some embodiments, the adhesive layer 12 may be disposed between the display panel 10 and the cover lens CP1. In some embodiments, the adhesive layer 12 may cover the bottom surface 20S1 of the substrate 20. In some embodiments, the adhesive layer 12 may include photo-curable adhesive, thermal-curable adhesive, photo-thermal curable adhesive, the like, or a combination thereof, but the present disclosure is not limited thereto. In some embodiments, the adhesive layer 12 may include optical clear adhesive (OCA), optical clear resin (OCR), pressure sensitive adhesive (PSA), the like, or a combination thereof, but the present disclosure is not limited thereto.

As shown in FIG. 1, in some embodiments, the electronic device 1 may further include a functional layer 50. In some embodiments, the cover lens CP1 may be disposed between the functional layer 50 and the display panel 10. In some embodiments, the functional layer 50 may be disposed on the top surface 20S2 of the substrate 20. For example, the functional layer 50 may include an anti-reflection layer, an anti-static layer, an anti-smudge layer, the like, or a combination thereof, but the present disclosure is not limited thereto.

In some embodiments, the display panel 10 may be provided. Then, the adhesive layer 12 may be formed on the display panel 10. In some embodiments, the substrate 20 may be provided. Then, the alignment mark 30 and the light-shielding layer 40 may be formed on the substrate 20 to form the cover lens CP1. In some embodiments, after the alignment mark 30 and the light-shielding layer 40 are formed on the substrate 20, the functional layer 50 may be further provided on the other side of the substrate 20 to form the cover lens CP1. Then, the position of the alignment mark 30 on the cover lens CP1 may be sensed by using an optical sensing device, such as a charge-coupled device (CCD), so that the cover lens CP1 is aligned with the display panels 10 with the adhesive layers 12 disposed thereon. Then, a bonding process is performed to improve the accuracy and/or process margin of the bonding process.

In the following, the alignment mark 30 will be described in detail.

In some embodiments, the transmittance may be measured by using the UV-visible spectrometer at a wavelength of 380 nm to 780 nm, but the present disclosure is not limited thereto. In other embodiments, the UV-visible spectrometer may perform a full wavelength scan, or may perform a specific wavelength scan, such as 550 nm.

In some embodiments, the alignment mark 30 may include an opaque ink material. In some embodiments, the transmittance of the opaque ink material may be less than or equal to 30%. For example, the transmittance of the opaque ink material may be 30%, 25%, 20%, 15%, 10%, 5%, 4%, 3%, 2%, 1%, or any value or any range of values between the aforementioned values, but the present disclosure is not limited thereto. In some embodiments, the alignment mark 30 may include black opaque material, blue opaque material, green opaque material, the like, or a combination thereof, but the present disclosure is not limited thereto. For example, the black opaque material may include black matrix, black glue, black photoresist materials, the like, or a combination thereof, but the present disclosure is not limited thereto.

In some embodiments, the viscosity of the opaque ink material may be less than or equal to 15 centipoise (cP). For example, the viscosity of the opaque ink material may be 15 cP, 14 cP, 13 cP, 12 cP, 11 cP, 10 cP, 9 cP, 8 cP, 7 cP, 6 cP, 5 cP, 4 cP, 3 cP, 2 cP, 1 cP, or any value or any range of values between the aforementioned values, but the present disclosure is not limited thereto.

In some embodiments, the alignment mark 30 may be formed by an inkjet printing process. Accordingly, by controlling the viscosity of the opaque ink material and the parameters of the inkjet printing process, the size of the ink dots and/or the number of times of the inkjet printing are performed (the number of ink dots) may be controlled, thereby adjusting the size of the alignment mark 30 formed by the opaque ink material. For example, the number of times of the inkjet printing may be reduced to simplify the process complexity and/or reduce the process cost.

In some embodiments, in the normal direction of the substrate 20, the alignment mark 30 does not overlap with the light-shielding layer 40. Accordingly, the alignment mark 30 may not occupy a position corresponding to the peripheral area PA of the display panel 10, and may be disposed at a position corresponding to the active area DA of the display panel 10, thereby facilitating application in a narrow-frame device. In some embodiments, since the alignment mark 30 is provided on the substrate 20, the bonding process may be performed by using the alignment mark 30 regardless of the shape of the substrate 20. For example, even if the edge of the substrate 20 is curved (that is, without an acute angle), the alignment can still be performed by the alignment mark 30.

In some embodiments, the alignment mark 30 and the light-shielding layer 40 may be formed in the same process. For example, the alignment mark 30 and the light-shielding layer 40 may both be formed by the inkjet printing process. Accordingly, since the alignment mark 30 and the light-shielding layer 40 may be formed in the same process, it is possible to avoid large tolerance (for example, the composite tolerance) caused by forming the alignment mark 30 and the light-shielding layer 40 in different processes and/or to reduce process complexity. Furthermore, since the alignment mark 30 and the light-shielding layer 40 may be formed in the same process, the cover lens CPI may be applied to a device with a narrow frame or a device with a curved edge.

In some embodiments, the alignment mark 30 and the light-shielding layer 40 may include or be formed of the same material. Accordingly, it is possible to avoid the limitation that the alignment mark 30 and the light-shielding layer 40 need to be formed of materials with contrasting colors to be sensed by the optical sensing device. Therefore, material selection may be simplified and/or process complexity may be reduced.

In some embodiments, according to the alignment requirements, the alignment mark 30 may include a plurality of alignment marks. In some embodiments, each of the plurality of alignment marks may correspond to each corner of the substrate 20, but the present disclosure is not limited thereto. In some embodiments, some corners of the substrate 20 are provided with alignment marks, and other corners of the substrate 20 are not provided with alignment marks. In some embodiments, each of the plurality of alignment marks may correspond to each of end points of the diagonal lines of the substrate 20, respectively.

In some embodiments, for illustration, the alignment mark 30 may include a first alignment mark 32 and a second alignment mark 34, but the present disclosure is not limited thereto. As shown in FIG. 1, in some embodiments, the first alignment mark 32 may correspond to the first position P1 of the active area DA, and the second alignment mark 34 may correspond to the second position P2 of the active area DA, and the first position P1 differs from the second position P2.

Referring to FIG. 2, which is a schematic bottom view of the cover lens CP1 of the electronic device 1 according to some embodiments of the present disclosure. FIG. 1 shows a schematic cross-sectional view taken along line I-I′ shown in FIG. 2. As shown in FIG. 2, in some embodiments, the first alignment mark 32 and the second alignment mark 34 correspond to respective end points of the diagonal line of the substrate 20. Accordingly, the position of the cover lens CP1 may be aligned using the alignment mark 30.

As shown in FIG. 2, the transmittance may be measured by using the UV-visible spectrometer at the wavelength of 380 nm to 780 nm. In some embodiments, the transmittance of the first alignment mark 32 in the first alignment region R1 may be 20% to 99%. For example, the transmittance of the first alignment mark 32 in the first alignment region R1 may be 20%, 30%, 40%, 50%, 60%, 70%, 80%, 85%, 90%, 92%, 94%, 96%, 98%, 99%, or any value or any range of values between the aforementioned values, but the present disclosure is not limited thereto. For example, the transmittance of the first alignment mark 32 in the first alignment region R1 may be 20% to 99%, 20% to 92%, or 20% to 85%. In some embodiments, the diameter dR1 of the first alignment region R1 may be 0.5 mm to 8 mm. For example, the diameter dR1 of the first alignment region R1 may be 0.5 mm, 1.5 mm, 1.75 mm, 2 mm, 2.25 mm, 2.5 mm, 3 mm, 4 mm, 5 mm, 6 mm, 7 mm, 8 mm, or any value or any range of values between the aforementioned values, but the present disclosure is not limited thereto. In some embodiments, the size of the first alignment region R1 may be substantially close to a size of a light spot generated by the UV-visible spectrometer for measurement or a size of a light spot of a charge-coupled device (CCD). For example, the diameter of the light spot generated by the UV-visible spectrometer may be 2 mm. For example, the diameter of the light spot of the charge-coupled device may be 7 mm.

Accordingly, even though the first alignment mark 32 may substantially include the opaque ink material, since the specific transmittance of the first alignment mark 32 in the first alignment region R1 is controlled, the first alignment mark 32 located in the active area DA will not be observed by the user. Therefore, the accuracy of the bonding process may be improved, and the first alignment mark 32 may be prevented from affecting the visual effect of the active area DA observed by user. For example, visual effects may include clarity, the presence of dark spots, or other visual effects.

As shown in FIG. 2, in some embodiments, the transmittance of the second alignment mark 34 in the second alignment region R2 is 20% to 99%. For example, the transmittance of the second alignment mark 34 in the second alignment region R2 may be 20%, 30%, 40%, 50%, 60%, 70%, 80%, 85%, 90%, 92%, 94%, 96%, 98%, 99%, or any value or any range of values between the aforementioned values, but the present disclosure is not limited thereto. For example, the transmittance of the second alignment mark 34 in the second alignment region R2 may be 20% to 99%, 20% to 92%, or 20% to 85%. In some embodiments, the diameter dR2 of the second alignment region R2 may be 0.5 mm to 8 mm. For example, the diameter dR2 of the second alignment region R2 may be 0.5 mm, 1.5 mm, 1.75 mm, 2 mm, 2.25 mm, 2.5 mm, 3 mm, 4 mm, 5 mm, 6 mm, 7 mm, 8 mm, or any value or any range of values between the aforementioned values, but the present disclosure is not limited thereto.

In some embodiments, the alignment mark 30 may include alignment marks with different shapes. For example, the alignment mark 30 may be a point shape, an elliptical shape, a polygonal shape with curved edges, the like, or a combination thereof, but the present disclosure is not limited thereto. In some embodiments, at least one of the first alignment mark 32 and the second alignment mark 34 (that is, one of the first alignment mark 32 and the second alignment mark 34, or both of the first alignment mark 32 and the second alignment mark 34) includes point shaped alignment marks. In some embodiments, the first alignment mark 32 and the second alignment mark 34 may respectively include point shaped alignment marks.

In some embodiments, the diameter of the point shaped alignment mark may be 50 um to 150 um. As shown in FIG. 2, in some embodiments, the first alignment mark 32 and the second alignment mark 34 may be point-shaped alignment marks, respectively. In some embodiments, the diameter d32 of the first alignment mark 32 may be 50 um to 150 um. For example, the diameter d32 may be 50 um, 60 um, 70 um, 80 um, 90 um, 100 um, 110 um, 120 um, 130 um, 140 um, 150 um, or any value or any range of values between the aforementioned values, but the present disclosure is not limited thereto. In some embodiments, the diameter d34 of the second alignment mark 34 may be 50 um to 150 um. For example, the diameter d34 may be 50 um, 60 um, 70 um, 80 um, 90 um, 100 um, 110 um, 120 um, 130 um, 140 um, 150 um, or any value or any range of values between the aforementioned values, but the present disclosure is not limited thereto. Accordingly, when the size of the point shaped alignment marks is at least equal to 50 um, it may be advantageous for the optical sensing device to sense the alignment marks. In some embodiments, the diameter d32 of the first alignment mark 32 and the diameter d34 of the second alignment mark 34 may be the same or different. Accordingly, when the diameters are different, it is more convenient for the optical sensing device to sense the alignment mark.

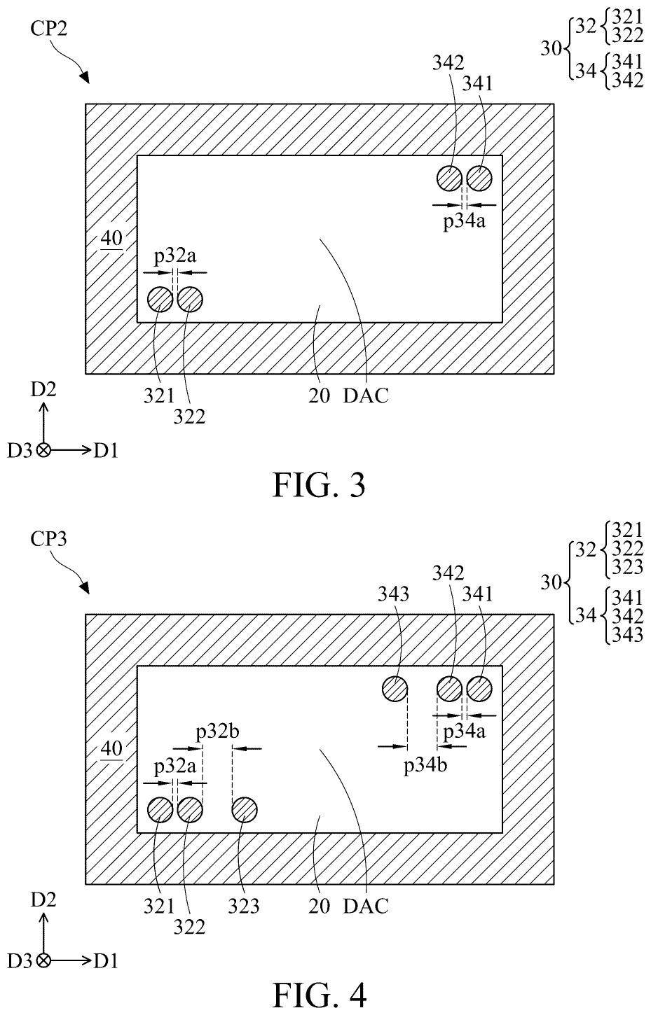

Referring to FIG. 3, which is a schematic bottom view of the cover lens CP2 of the electronic device according to some embodiments of the present disclosure. As shown in FIG. 3, in some embodiments, the first alignment mark 32 may include a plurality of first sub-alignment marks. In some embodiments, the number of first sub-alignment marks may be 1 to 50, but the present disclosure is not limited thereto. For example, the number of the first sub-alignment marks may be 1, 2, 3, 4, 5, 10, 15, 20, 25, 30, 35, 40, 45, 50, or any value or any range of values between the aforementioned values, but the present disclosure is not limited thereto. For example, the number of the first sub-alignment marks may be 1 to 50, 1 to 30, 1 to 20, 1 to 10, but the present disclosure is not limited thereto.

As shown in FIG. 3, in some embodiments, the first alignment mark 32 may include at least two first sub-alignment marks 321 and 322. In some embodiments, the at least two first sub-alignment marks 321 and 322 may be point-shaped. In some embodiments, the pitch p32a between the at least two first sub-alignment marks 321 and 322 may be 0.001 mm to 0.1 mm. For example, the pitch p32a may be 0.001 mm, 0.0025 mm, 0.005 mm, 0.0075 mm, 0.01 mm, 0.025 mm, 0.05 mm, 0.075 mm, 0.1 mm, or any value or any range of values between the aforementioned values, but the present disclosure is not limited thereto. In some embodiments, the first sub-alignment marks 321 and 322 may be arranged along the first direction D1.

In the following, the second alignment mark 34 or other alignment marks (for example, the third alignment mark and the fourth alignment mark described below) may be designed in the same or similar manner as the first alignment mark 32.

As shown in FIG. 3, in some embodiments, the second alignment mark 34 may include a plurality of second sub-alignment marks. In some embodiments, the number of second sub-alignment marks may be 1 to 50, but the present disclosure is not limited thereto. For example, the number of the second sub-alignment marks may be 1, 2, 3, 4, 5, 10, 15, 20, 25, 30, 35, 40, 45, 50, or any value or any range of values between the aforementioned values, but the present disclosure is not limited thereto. For example, the number of the second sub-alignment marks may be 1 to 50, 1 to 30, 1 to 20, 1 to 10, but the present disclosure is not limited thereto.

As shown in FIG. 3, in some embodiments, the second alignment mark 34 may include at least two second sub-alignment marks 341 and 342. In some embodiments, the at least two second sub-alignment marks 341 and 342 may be point-shaped. In some embodiments, the pitch p34a between the at least two second sub-alignment marks 341 and 342 may be 0.001 mm to 0.1 mm. For example, the pitch p34a may be 0.001 mm, 0.0025 mm, 0.005 mm, 0.0075 mm, 0.01 mm, 0.025 mm, 0.05 mm, 0.075 mm, 0.1 mm, or any value or any range of values between the aforementioned values, but the present disclosure is not limited thereto. In some embodiments, the second sub-alignment marks 341 and 342 may be arranged along the first direction D1.

Referring to FIG. 4, which is a schematic bottom view of the cover lens CP3 of the electronic device according to some embodiments of the present disclosure. As shown in FIG. 4, in some embodiments, the first alignment mark 32 may include three first sub-alignment marks 321, 322, and 323, and the second alignment mark 34 may include three second sub-alignment marks 341, 342, and 343. In some embodiments, the pitch between the first sub-alignment marks increases toward the center DAC of the active area DA. For example, the pitch may be gradually increased, step increased, or otherwise increased, but the present disclosure is not limited thereto. As shown in FIG. 4, in some embodiments, the pitch p32a between the first sub-alignment marks 321 and 322 may be smaller than the pitch p32b between the first sub-alignment marks 322 and 323. In some embodiments, the ratio between the pitch p32a and the pitch p32b (the pitch p32a/the pitch p32b) may be less than or equal to 0.5. For example, the ratio between the pitch p32a and the pitch p32b may be 0.5, 0.4, 0.3, 0.2, 0.1, 0.05, 0.01, or any value or any range of values between the aforementioned values, but the present disclosure is not limited thereto. Accordingly, the density of the first sub-alignment marks near the center DAC of the active area DA may be lower, which can prevent the first sub-alignment marks from affecting the visual effect of the active area DA observed by user.

As shown in FIG. 4, in some embodiments, the pitch between the second sub-alignment marks also increases toward the center DAC of the active area DA. In some embodiments, the pitch p34a between the second sub-alignment marks 341 and 342 may be less than the pitch p34b between the second sub-alignment marks 342 and 343. In some embodiments, the ratio between the pitch p34a and the pitch p34b (the pitch p34a/the pitch p34b) may be less than or equal to 0.5. Accordingly, the density of the second sub-alignment marks near the center DAC of the active area DA may be lower, which can prevent the second sub-alignment marks from affecting the visual effect of the active area DA observed by user. In some embodiments, the ratio between the pitch p32a and the pitch p32b and the ratio between the pitch p34a and the pitch p34b may be the same or different. Accordingly, when the pitch is different, it is more convenient for the optical sensing device to sense the alignment mark.

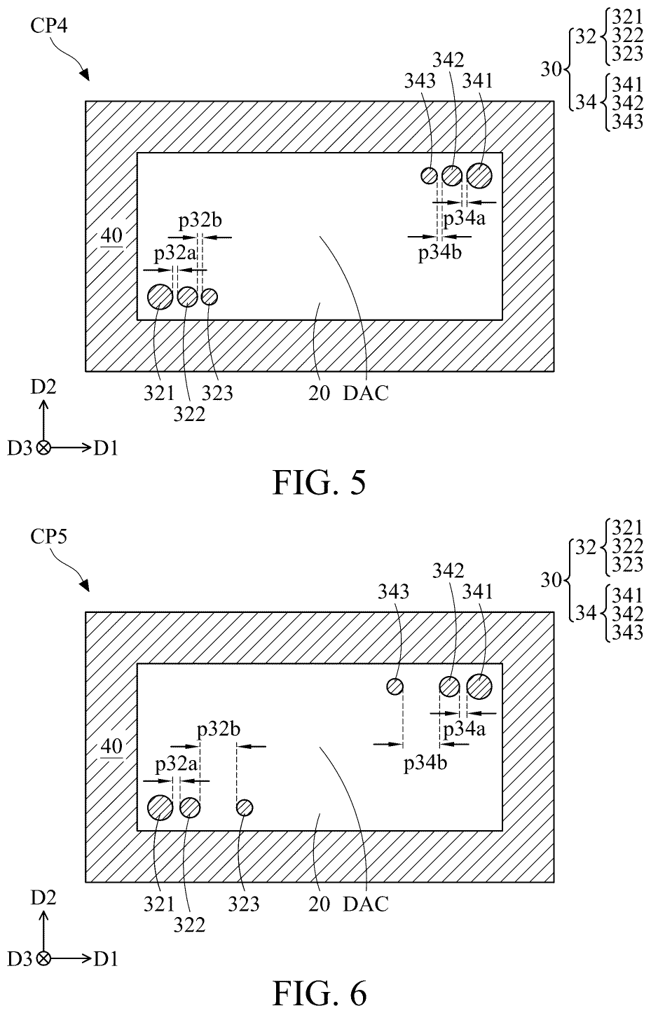

Referring to FIG. 5, which is a schematic bottom view of the cover lens CP4 of the electronic device according to some embodiments of the present disclosure. As shown in FIG. 5, in some embodiments, the areas of the first sub-alignment marks decrease toward the center DAC of the active area DA. For example. The area may be gradually reduced, steps reduced, or otherwise reduced, but the present disclosure is not limited thereto. In some embodiments, the area of the first sub-alignment mark 321 may be greater than the area of the first sub-alignment mark 322, and the area of the first sub-alignment mark 322 may be greater than the area of the first sub-alignment mark 323. In some embodiments, the ratio of the area of the first sub-alignment mark 321 to the area of the first sub-alignment mark 322 (the area of the first sub-alignment mark 321/the area of first sub-alignment mark 322) or the ratio of the area of the first sub-alignment mark 322 to the area of the first sub-alignment mark 323 (the area of the first sub-alignment mark 322/the area of the first sub-alignment mark 323) may be greater than or equal to 1.2. For example, the ratio of the areas may be 1.2, 1.5, 2, 2.5, 3, 3.5, 4, 4.5, 5, or any value or any range of values between the aforementioned values, but the present disclosure is not limited thereto. Accordingly, the density of the first sub-alignment marks near the center DAC of the active area DA may be lower, which can prevent the first sub-alignment mark from affecting the visual effect of the active area DA observed by user.

As shown in FIG. 5, in some embodiments, the areas of the second sub-alignment marks decrease toward the center DAC of the active area DA. In some embodiments, the area of the second sub-alignment mark 341 may be greater than the area of the second sub-alignment mark 342, and the area of the second sub-alignment mark 342 may be greater than the area of the second sub-alignment mark 343. In some embodiments, the ratio of the area of the second sub-alignment mark 341 to the area of the second sub-alignment mark 342 (the area of the second sub-alignment mark 341/the area of the second sub-alignment mark 342) or the ratio of the area of the second sub-alignment mark 342 to the area of the second sub-alignment mark 343 (the area of the second sub-alignment mark 342/the area of the second sub-alignment mark 343) may be greater than or equal to 1.2. Accordingly, the density of the second sub-alignment marks near the center DAC of the active area DA may be lower, which can prevent the second sub-alignment mark from affecting the visual effect of the active area DA observed by the user. In some embodiments, the ratio of the areas of the first sub-alignment marks and the ratio of the areas of the second sub-alignment marks may be the same or different. Accordingly, when the ratios of areas are different, it may be more convenient for the optical sensing device to sense the alignment mark.

Referring to FIG. 6, which is a schematic bottom view of the cover lens CP5 of the electronic device according to some embodiments of the present disclosure. As shown in FIG. 6, in some embodiments, the pitches p32a and p32b increase toward the center DAC of the active area DA, and the areas of the first sub-alignment marks 321 to 323 decrease toward the center DAC of the active area DA. In some embodiments, the pitches p34a and p34b increase toward the center DAC of the active area DA, and the areas of the second sub-alignment marks 341 to 343 decrease toward the center DAC of the active area DA.

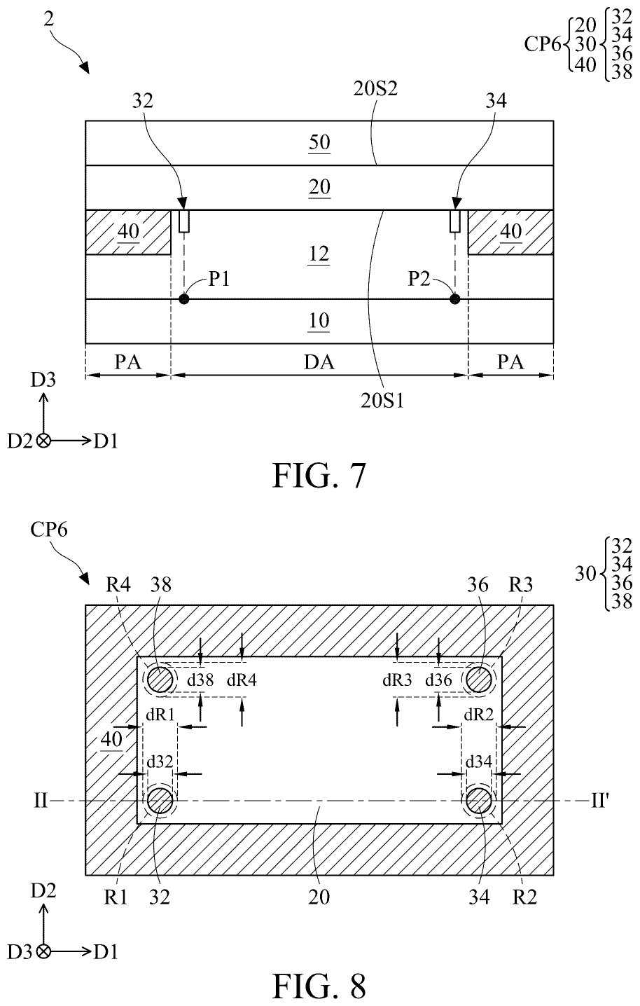

Referring to FIG. 7, which is a schematic cross-sectional view of the electronic device 2 according to some embodiments of the present disclosure. In some embodiments, the alignment mark 30 of the cover lens CP6 may include the first alignment mark 32, the second alignment mark 34, a third alignment mark 36, and a fourth alignment mark 38.

Referring to FIG. 8, which is a schematic bottom view of the cover lens CP6 of the electronic device 2 according to some embodiments of the present disclosure. FIG. 7 shows a schematic cross-sectional view taken along line II-II′ shown in FIG. 8. In some embodiments, the transmittance may be measured by using the UV-visible spectrometer at a wavelength of 380 nm to 780 nm. In some embodiments, the transmittance of the third alignment mark 36 in a third alignment region R3 may be 20% to 99%, and the transmittance of the fourth alignment mark 38 in a fourth alignment region R4 may be 20% to 99%. In some embodiments, the diameter dR3 of the third alignment region R3 may be 0.5 mm to 8 mm, and the diameter dR4 of the fourth alignment region R4 may be 0.5 mm to 8 mm. In some embodiments, the third alignment mark 36 and the fourth alignment mark 38 may be point-shaped alignment marks, respectively. In some embodiments, the diameter d36 of the third alignment mark 36 and the diameter d38 of the fourth alignment mark 38 may be 50 um to 150 um, respectively.

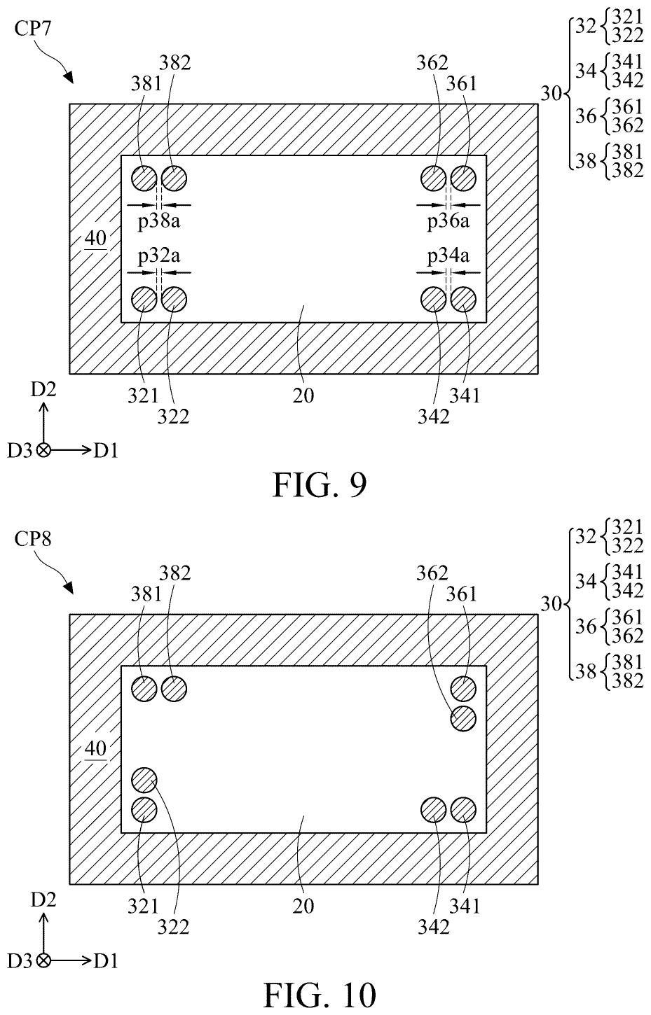

Referring to FIG. 9, which is a schematic bottom view of the cover lens CP7 of the electronic device according to some embodiments of the present disclosure. In some embodiments, the third alignment mark 36 may include third sub-alignment marks 361 and 362, and the fourth alignment mark 38 may include fourth sub-alignment marks 381 and 382. In some embodiments, the pitch p36a between the third sub-alignment marks 361 and 362 may be 0.001 mm to 0.1 mm, and the pitch p38a between the fourth sub-alignment marks 381 and 382 may be 0.001 mm to 0.1 mm.

Referring to FIG. 10, which is a schematic bottom view of the cover lens CP8 of the electronic device according to some embodiments of the present disclosure. As shown in FIG. 10, in some embodiments, the first sub-alignment marks 321 and 322 may be arranged along the second direction D2, and the second sub-alignment marks 341 and 342 may be arranged along the first direction D1. In some embodiments, the third sub-alignment marks 361 and 362 may be arranged along the second direction D2, and the fourth sub-alignment marks 381 and 382 may be arranged along the first direction D1.

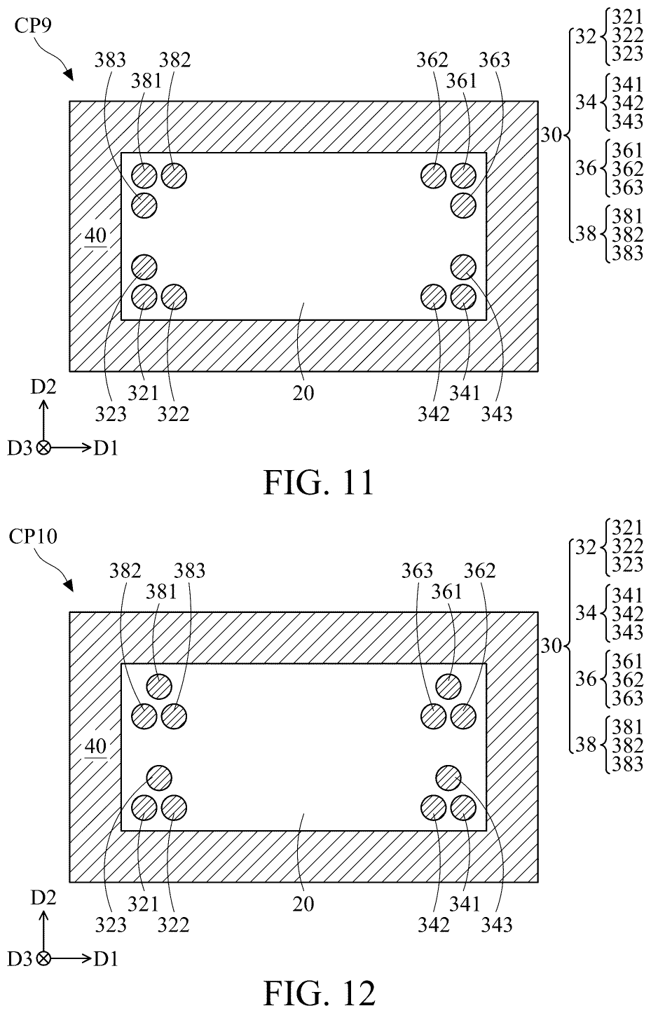

Referring to FIG. 11, which is a schematic bottom view of the cover lens CP9 of the electronic device according to some embodiments of the present disclosure. As shown in FIG. 11, in some embodiments, the first alignment mark 32 may include three first sub-alignment marks 321 to 323, the second alignment mark 34 may include three second sub-alignment marks 341 to 343, the third alignment mark 36 may include three third sub-alignment marks 361 to 363, and the fourth alignment mark 38 may include three fourth sub-alignment marks 381 to 383. In some embodiments, the first sub-alignment marks 321 to 323, the second sub-alignment marks 341 to 343, the third sub-alignment marks 361 to 363, and the fourth sub-alignment marks 381 to 383 may be arranged along the shape of the corner of the substrate 20, respectively.

Referring to FIG. 12, which is a schematic bottom view of the cover lens CP10 of the electronic device according to some embodiments of the present disclosure. As shown in FIG. 12, in some embodiments, the first sub-alignment marks 321 to 323, the second sub-alignment marks 341 to 343, the third sub-alignment marks 361 to 363, and the fourth sub-alignment mark 381 to 383 may be respectively arranged in the shape of an equilateral triangle, but the present disclosure is not limited thereto.

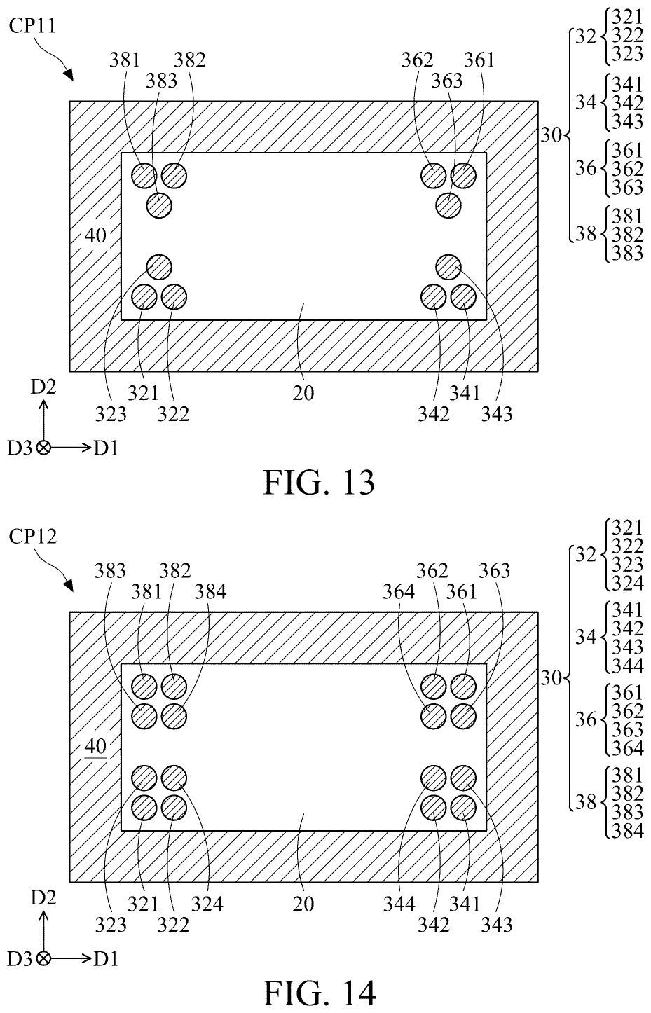

Referring to FIG. 13, which is a schematic bottom view of the cover lens CP11 of the electronic device according to some embodiments of the present disclosure. As shown in FIG. 13, in some embodiments, the first sub-alignment marks 321 to 323 and the second sub-alignment marks 341 to 343 may be respectively arranged in the shape of an equilateral triangle, and the third sub-alignment marks 361 to 363 and the fourth sub-alignment marks 381 to 383 may be respectively arranged in the shape of an inverted triangle, but the present disclosure is not limited thereto.

Referring to FIG. 14, which is a schematic bottom view of the cover lens CP12 of the electronic device according to some embodiments of the present disclosure. As shown in FIG. 14, in some embodiments, the first alignment mark 32 may include four first sub-alignment marks 321 to 324, the second alignment mark 34 may include four second sub-alignment marks 341 to 344, the third alignment mark 36 may include four third sub-alignment marks 361 to 364, and the fourth alignment mark 38 may include four fourth sub-alignment marks 381 to 384. As shown in FIG. 14, in some embodiments, the first sub-alignment marks 321 to 324, the second sub-alignment marks 341 to 344, the third sub-alignment marks 361 to 364, and the fourth sub-alignment mark 381 to 384 may be respectively arranged in a square shape, but the present disclosure is not limited thereto.

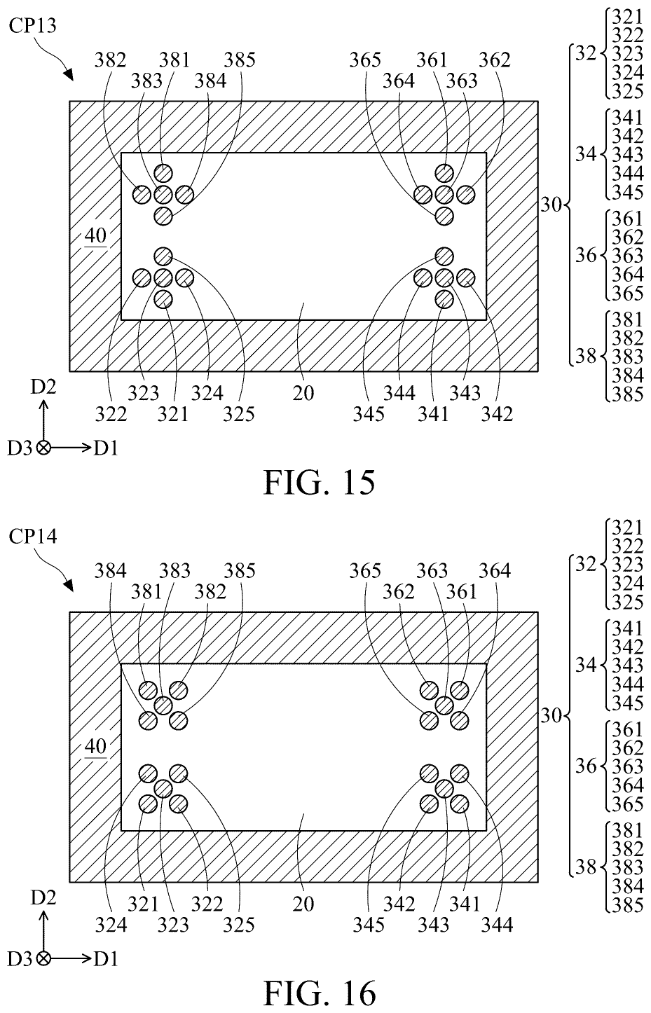

Referring to FIG. 15, which is a schematic bottom view of the cover lens CP13 of the electronic device according to some embodiments of the present disclosure. As shown in FIG. 15, in some embodiments, the first alignment mark 32 may include five first sub-alignment marks 321 to 325, the second alignment mark 34 may include five second sub-alignment marks 341 to 345, the third alignment mark 36 may include five third sub-alignment marks 361 to 365, and the fourth alignment mark 38 may include five fourth sub-alignment marks 381 to 385. As shown in FIG. 15, in some embodiments, the first sub-alignment marks 321 to 325, the second sub-alignment marks 341 to 345, the third sub-alignment marks 361 to 365, and the fourth sub-alignment mark 381 to 385 may be respectively arranged in a cross shape, but the present disclosure is not limited thereto.

Referring to FIG. 16, which is a schematic bottom view of the cover lens CP14 of the electronic device according to some embodiments of the present disclosure. As shown in FIG. 16, in some embodiments, the first sub-alignment marks 321 to 325, the second sub-alignment marks 341 to 345, the third sub-alignment marks 361 to 365, and the fourth sub-alignment mark 381 to 385 may be respectively arranged in an X shape, but the present disclosure is not limited thereto.

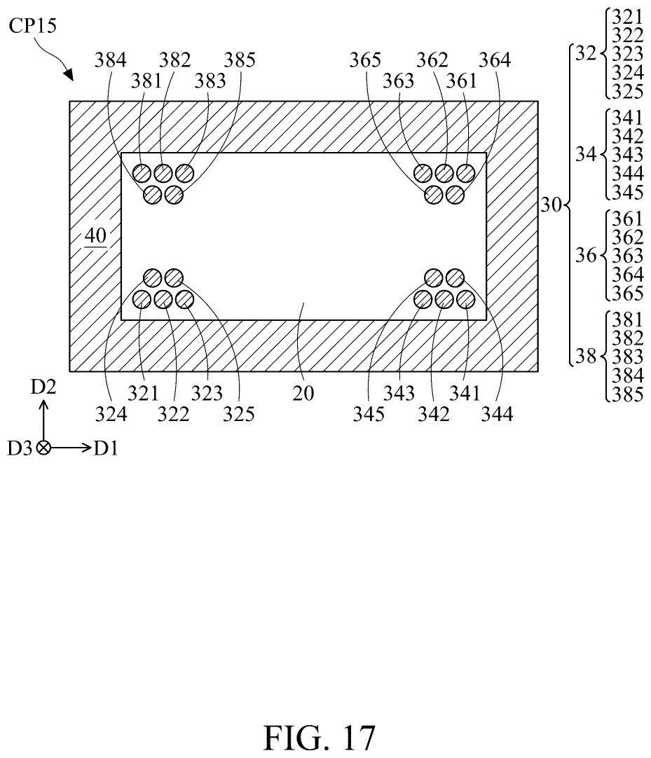

Referring to FIG. 17, which is a schematic bottom view of the cover lens CP15 of the electronic device according to some embodiments of the present disclosure. As shown in FIG. 17, in some embodiments, the first sub-alignment marks 321 to 325, the second sub-alignment marks 341 to 345, the third sub-alignment marks 361 to 365, and the fourth sub-alignment mark 381 to 385 may be respectively arranged in a trapezoidal shape, but the present disclosure is not limited thereto.

In some embodiments, one or more of the cover lenses CP1 to CP15 may be used in any combination. In some embodiments, one or more of the cover lenses CP1 to CP15 may be applied to a device with a narrow frame or a device with a curved edge.

Accordingly, the present disclosure may improve the visual effect and/or the reliability of the electronic device, the accuracy and/or the process margin of the bonding process by disposing alignment marks (for example, the first alignment marks, the second alignment marks, the third alignment marks, and/or the fourth alignment marks) with specific transmittance. For example, the present disclosure may select alignment marks with a specific transmittance (for example, 20% to 99%), and may prevent the alignment marks from affecting the visual effects of the active area observed by user's while improving the accuracy of the bonding process. In addition, by forming the alignment mark and the light-shielding layer in the same process, the tolerance in forming the alignment mark may be reduced, thereby further improving the reliability of the electronic device. Furthermore, by using the same material to form the alignment mark and the light-shielding layer, the restriction on material selection for the alignment mark may be reduced. In addition, the electronic device of the present disclosure may be used in combination with an optical sensing device to improve the process margin of the bonding process.

The features among the various embodiments of the present disclosure may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the above-mentioned process, machine, manufacturing, material composition, device, method, and steps. The protection scope of the present disclosure shall be determined by the scope of the claims. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A electronic device, comprising:
a display panel having an active area; and
a cover lens disposed corresponding to the display panel and comprising:
a substrate;
a first alignment mark disposed on a surface of the substrate and corresponding to a first position in the active area; and
a second alignment mark disposed on the surface of the substrate and corresponding to a second position in the active area, wherein the second position differs from the first position,
wherein a transmittance of the first alignment mark in a first alignment region is 20% to 99%.

2. The electronic device as claimed in claim 1, wherein a diameter of the first alignment region is 0.5 mm to 8 mm.

3. The electronic device as claimed in claim 1, wherein a transmittance of the second alignment mark in a second alignment region is 20% to 99%.

4. The electronic device as claimed in claim 3, wherein a diameter of the second alignment region is 0.5 mm to 8 mm.

5. The electronic device as claimed in claim 1, wherein at least one of the first alignment mark and the second alignment mark comprises a point-shaped alignment mark.

6. The electronic device as claimed in claim 5, wherein a diameter of the point-shaped alignment mark is 50 um to 150 um.

7. The electronic device as claimed in claim 1, wherein the first alignment mark and the second alignment mark comprise opaque ink material.

8. The electronic device as claimed in claim 7, wherein a viscosity of the opaque ink material is less than or equal to 15 centipoise (cP).

9. The electronic device as claimed in claim 1, wherein the first alignment mark comprises at least two first sub-alignment marks, and the at least two first sub-alignment marks are point-shaped, and a pitch between the at least two first sub-alignment marks is 0.001 mm to 0.1 mm.

10. The electronic device as claimed in claim 9, wherein the pitch between the at least two first sub-alignment marks increases toward a center of the active area.

11. The electronic device as claimed in claim 9, wherein an area of the at least two first sub-alignment marks decreases toward a center of the active area.

12. The electronic device as claimed in claim 9, wherein the second alignment mark comprises at least two second sub-alignment marks, and the at least two second sub-alignment marks are point-shaped, and a pitch between the at least two second sub-alignment marks is 0.001 mm to 0.1 mm.

13. The electronic device as claimed in claim 12, wherein the pitch between the at least two second sub-alignment marks increases toward a center of the active area.

14. The electronic device as claimed in claim 12, wherein an area of the at least two second sub-alignment marks decreases toward a center of the active area.

15. The electronic device as claimed in claim 1, wherein the first alignment mark and the second alignment mark are formed by an inkjet printing process.

16. The electronic device as claimed in claim 1, wherein the cover lens further comprises:
a light-shielding layer disposed on the surface of the substrate and corresponding to a peripheral area of the display panel.

17. The electronic device as claimed in claim 16, wherein the light-shielding layer surrounds the first alignment mark and the second alignment mark.

18. The electronic device as claimed in claim 16, wherein the light-shielding layer, the first alignment mark, and the second alignment mark are formed in the same process.

19. The electronic device as claimed in claim 1, further comprising:
an adhesive layer disposed between the display panel and the cover lens.

20. The electronic device as claimed in claim 1, further comprising:
a functional layer disposed on the cover lens, wherein the cover lens is disposed between the functional layer and the display panel.
